(19) United States
(12) Patent Application Publication
(10) Pub. No.: US 2026/0358385 A1
(43) Pub. Date: Nov. 12, 2026

(54) IN-SITU LEAKAGE CURRENT COMPENSATION TECHNIQUE FOR VOLTAGE MEASUREMENT OF A COMPLEMENTARY METAL OXIDE SEMICONDUCTOR ANALOG MULTIPLEXER SWITCH

(71) Applicant: Lumentum Operations LLC, San Jose, CA (US)

(72) Inventors: Dusan IVANCEVIC, Ottawa (CA); Srikanth RAMAKRISHNAN, Ottawa (CA); Scott BRADFORD, Ottawa (CA); Philip RUDDOCK, Ottawa (CA)

(21) Appl. No.: 19/254,494

(22) Filed: Jun. 30, 2025

Related U.S. Application Data
(60) Provisional application No. 63/801,025, filed on May 6, 2025.

(51) Int. Cl. G01R 19/25

(52) U.S. Cl. CPC G01R 19/2509

(57) ABSTRACT

A voltage measurement system includes a first analog buffer amplifier, a second analog buffer amplifier, a resistor, a selector switch, a digital-to-analog converter (DAC), and an analog-to-digital converter (ADC). A first input of the ADC is connected to an output of a complementary metal oxide semiconductor (CMOS) analog multiplexer switch via the first analog buffer amplifier. The DAC is operable to connect to the output of the CMOS analog multiplexer switch via the resistor and to a second input of the ADC via the second analog buffer amplifier when the SPDT is in a first position. The DAC is operable to not connect to the output of the CMOS analog multiplexer switch via the resistor and to the second input of the ADC via the second analog buffer amplifier when the SPDT is in a second position.

### CROSS-REFERENCE TO RELATED APPLICATION

This Patent Application claims priority to U.S. Patent Application No. 63/801,025, filed on May 6, 2025, and entitled “High Voltage Digital to Analog Converter Complementary Metal Oxide Semiconductor Multiplexed Voltage Measurement Using an In-situ Leakage Current Compensation Technique.” The disclosure of the prior Application is considered part of and is incorporated by reference into this Patent Application.

### TECHNICAL FIELD

The present disclosure relates generally to a voltage measurement of a complementary metal oxide semiconductor (CMOS) analog multiplexer switch and to an in-situ leakage current compensation technique for voltage measurement of a CMOS analog multiplexer switch.

### BACKGROUND

A CMOS analog multiplexer switch is an integrated circuit that uses CMOS transistors (also referred to as switches or gates) to selectively route one of several analog input signals to a single output (or vice versa).

### SUMMARY

In some implementations, a voltage measurement system includes a first analog buffer amplifier; a second analog buffer amplifier; a resistor; a single pole, double throw (SPDT) switch; a digital-to-analog converter (DAC); and an analog-to-digital converter (ADC), wherein: a first input of the ADC is connected to an output of a CMOS analog multiplexer switch via the first analog buffer amplifier, the DAC is operable to connect to the output of the CMOS analog multiplexer switch via the resistor and to a second input of the ADC via the second analog buffer amplifier when the SPDT is in a first position, and the DAC is operable to not connect to the output of the CMOS analog multiplexer switch via the resistor and to the second input of the ADC via the second analog buffer amplifier when the SPDT is in a second position.

In some implementations, a micro-electro-mechanical systems (MEMS) device includes a resistor; an SPDT switch; a DAC; an ADC; and a controller, wherein: a first input of the ADC is connected to an output of a CMOS analog multiplexer switch of the MEMS device, and the DAC is operable to connect to the output of the CMOS analog multiplexer switch via the resistor and to a second input of the ADC when the SPDT is in a first position.

In some implementations, a method includes causing, by a controller of a voltage measurement system, a DAC, of the voltage measurement system, that is operably connected, via a selector switch, to an output of a CMOS analog multiplexer switch to perform a voltage sweep operation when the CMOS analog multiplexer switch is in a deactivated state and the selector switch is in a first position; causing, by the controller, an ADC that is operably connected to the DAC via the selector switch and connected to an output of the CMOS analog multiplexer switch to obtain first ADC counts associated with the DAC and the voltage sweep operation and second ADC counts associated with the output of the CMOS analog multiplexer switch and the voltage sweep operation; causing, by the controller, the CMOS analog multiplexer switch to perform a sequential input switch activation operation after completion of the voltage sweep operation and when the selector switch in a second position; causing, by the controller, the ADC to obtain third

ADC counts associated with input switches of the CMOS analog multiplexer switch and the sequential input switch activation operation; and determining, by the controller, fourth ADC counts associated with the input switches of the CMOS analog multiplexer switch based on the first ADC counts, the second ADC counts, and the third ADC counts.

### BRIEF DESCRIPTION OF THE DRAWINGS

FIGS. 1A-1B show an example configuration of a MEMS device that includes a CMOS analog multiplexer switch.

FIGS. 2A-2B are diagrams of an example implementation associated with an in-situ leakage current compensation technique for voltage measurement of a CMOS analog multiplexer switch.

FIGS. 3A-3C are diagrams of an example implementation associated with an in-situ leakage current compensation technique for voltage measurement of a CMOS analog multiplexer switch.

FIG. 4 is a diagram of example components of a device associated with an in-situ leakage current compensation technique for voltage measurement of a complementary metal oxide semiconductor analog multiplexer switch.

FIG. 5 is a flowchart of an example process associated with an in-situ leakage current compensation technique for voltage measurement of a CMOS analog multiplexer switch.

### DETAILED DESCRIPTION

The following detailed description of example implementations refers to the accompanying drawings. The same reference numbers in different drawings may identify the same or similar elements.

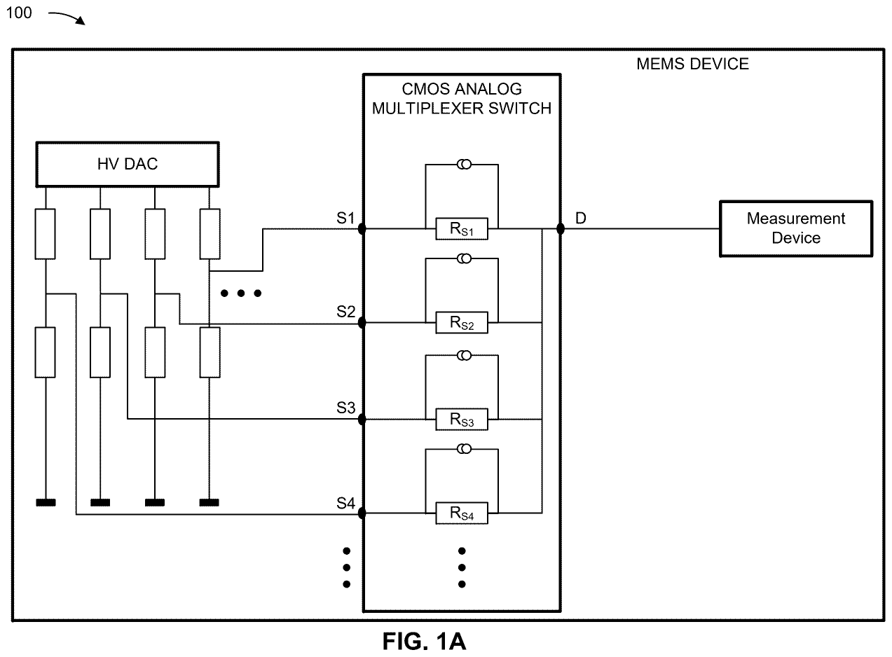

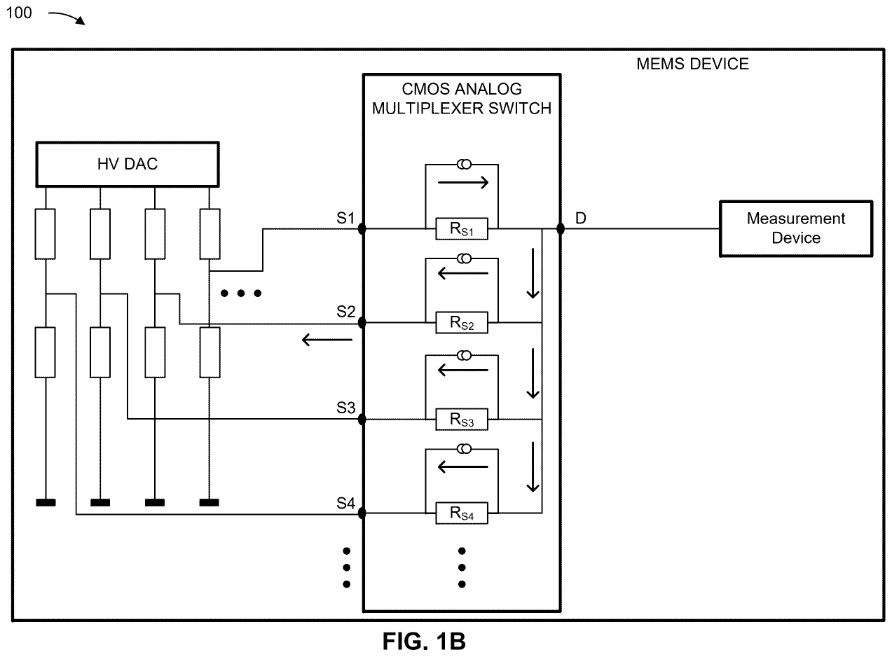

FIGS. 1A-1B show an example configuration 100 of a MEMS device that includes a high-voltage (HV) DAC (e.g., a DAC capable of outputting a hundred volts or more) that is connected to a CMOS analog multiplexer switch via a resistive network. Thus, the HV DAC is connected to the CMOS analog multiplexer switch via respective sets of resistors and respective inputs (shown as S1, S2, and so on) of the CMOS analog multiplexer switch. Each input is connected to an output (shown as D) of the CMOS analog multiplexer switch via an individual switch, or gate, of the CMOS analog multiplexer switch. Each switch may be associated with a particular resistance (e.g., R_{S1} for input S1, R_{S2} for input S2, and so on) and may be associated with a particular capacitance (e.g., shown as overlapping circles), which may be considered de minimis, such as on the order of a few picofarads (pF) with respect to voltage measurements and leakage currents further described herein.

A measurement device, such as a digital voltmeter (DVM), can be connected to an output (shown as D) of the CMOS analog multiplexer switch to facilitate voltage measurements of the inputs of the CMOS analog multiplexer switch. The measurement device can measure a voltage of a particular input of the CMOS analog multiplexer switch by, for example, measuring the output of the CMOS analog multiplexer switch when the particular input is activated and all other inputs are deactivated.

However, the CMOS analog multiplexer switch suffers from leakage currents (shown as arrows in FIG. 1B). The leakage currents arise from potential differences between each input

S and the output D of the CMOS analog multiplexer switch. For example, leakage currents can arise from parasitic current paths related to input and output connections and associated protection circuitry, as well as from individual switches within the CMOS analog multiplexer switch. The leakage currents can flow in various directions, such as from input to output or output to input. The direction and magnitude of the leakage currents depend on the voltage present at each input and on which input is activated or deactivated. Further, the leakage currents are at least partially a function of ambient temperature, often causing the leakage currents to fluctuate over long time intervals (e.g., on the order of tens of seconds or more) as ambient temperature changes.

In some cases, the leakage currents further flow through the resistive network, which can alter the voltage of an input. This alteration can introduce a measurement error at the connected measurement device. For example, in a scenario where a 5 nanoAmps (nA) leakage current flows through a 121 kiloOhm (kΩ) resistor that is in parallel with a 5 megaOhm (MΩ) resistor, a resulting voltage drop of approximately 0.6 millivolt (mV) is produced across the 121 kΩ resistor. Furthermore, when there is an input voltage divider network for that input, this 0.6 mV error can be amplified, potentially by tens of times. Consequently, in some cases, a resulting uncertainty in the measurement can be around 25 mV or more, which often exceeds acceptable uncertainty tolerances (e.g., 10 mV or less). This is particularly true given that other error sources, such as voltage reference inaccuracies, manufacturing tolerances and drifts in the resistors, and various other factors, also contribute to overall measurement error.

Some implementations described herein include a MEMS device. The MEMS device includes an HV DAC, a CMOS analog multiplexer switch, and a voltage measurement system. The HV DAC is connected to inputs of the CMOS analog multiplexer switch via a resistive network and the voltage measurement system is connected to an output of the CMOS analog multiplexer switch. The voltage measurement system includes a first analog buffer amplifier, a second analog buffer amplifier, a resistor, a selector switch, a DAC, an ADC, and a controller. A first input of the ADC is connected to the output of the CMOS analog multiplexer switch via the first analog buffer amplifier. The DAC is operable to connect to the output D of the CMOS analog multiplexer switch via the resistor and to a second input of the ADC via the second analog buffer amplifier when the selector switch is in a first position. Further, the DAC is operable to not connect to the output of the CMOS analog multiplexer switch (e.g., via the resistor) and to the second input of the ADC (e.g., via the second analog buffer amplifier) when the selector switch is in a second position.

In some implementations, the controller causes the CMOS analog multiplexer switch to be in a deactivated state (and all voltages of the inputs of the CMOS analog multiplexer switch to be constant) and causes, when the selector switch is in the first position, the DAC to perform a voltage sweep operation and the ADC to obtain first ADC counts (e.g., that indicate measured voltages at the DAC during the voltage sweep operation) and second ADC counts (e.g., that indicate measured voltages at the output of the CMOS analog multiplexer during the voltage sweep operation). In this way, the controller obtains information that indicates ADC count error due to leakage currents in the CMOS analog multiplexer switch (e.g., for particular voltages of the voltage sweep operation).

The controller then causes the CMOS analog multiplexer switch to perform a sequential input switch activation operation after completion of the voltage sweep operation, when the selector switch in a second position. The controller thereby causes the ADC to obtain third ADC counts (e.g., that indicate respective voltages of the inputs of the CMOS analog multiplexer switch during the sequential input switch activation operation). The controller then determines fourth ADC counts (e.g., that indicate leakage-current-corrected voltages of the input switches of the CMOS analog multiplexer switch), such as by determining, based on the first and second counts, ADC count errors due to leakage currents and then correcting the third counts using the ADC count errors.

In this way, some implementations described herein utilize an in-situ leakage current compensation technique for voltage measurement of a CMOS analog multiplexer switch. Further, operations described herein improve voltage measurements of the inputs of the CMOS analog multiplexer switch such that any error is reduced to be within practical tolerances for certain applications, such as in association with powering and controlling a MEMS device. Additionally, operations described herein are performed within a time window, which may be on the order of 100 milliseconds (msec) or less. Due to the limited time window, the influence of ambient temperature fluctuations on components of the MEMS device is minimized. Additionally, in some implementations, the operations described herein are performed iteratively on a scheduled basis, such as every few seconds, minutes, or longer, allowing leakage-current-corrected voltages to be repeatedly determined and updated to compensate for gradual changes in ambient temperature over time.

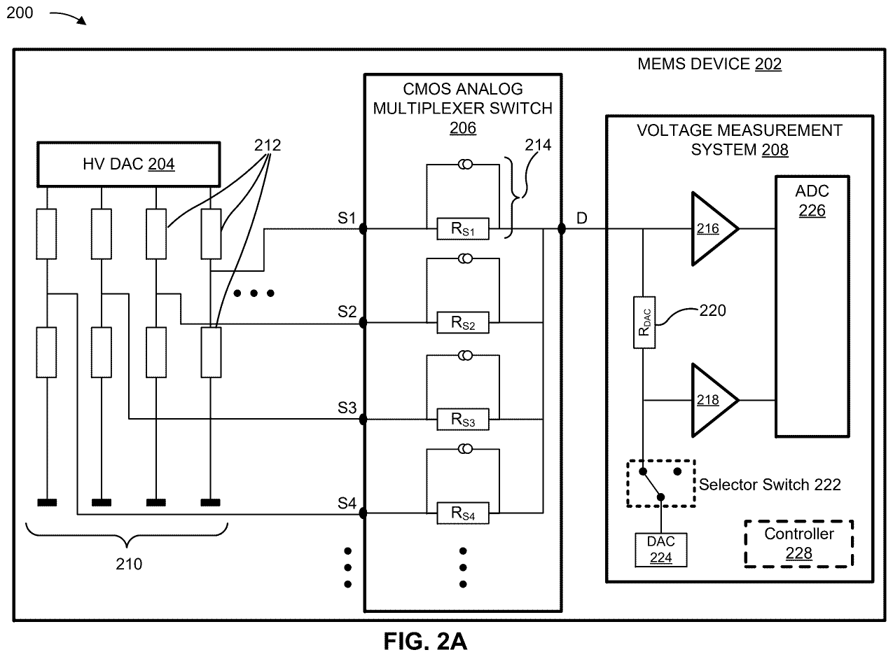

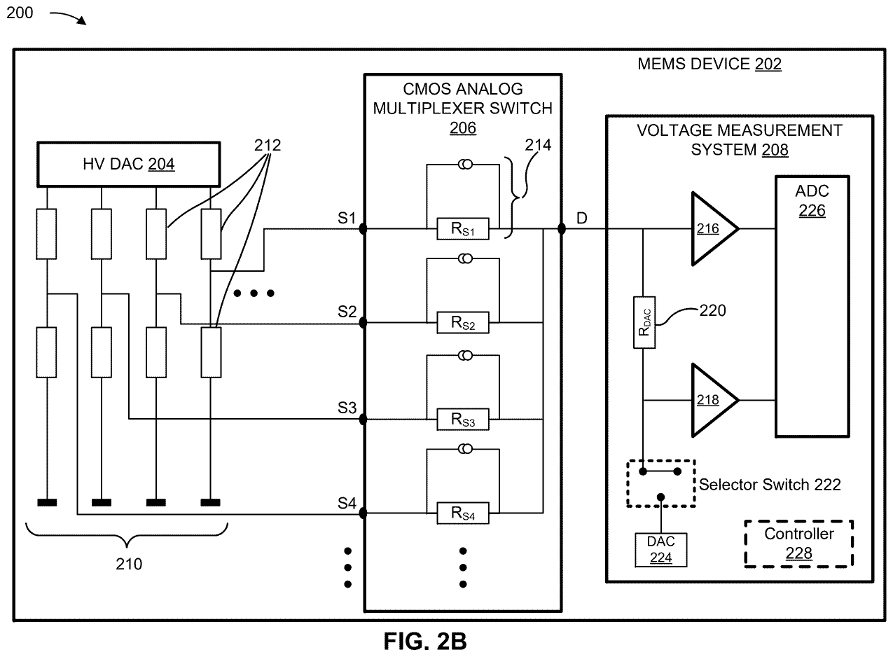

FIGS. 2A-2B are diagrams of an example implementation 200 associated with an in-situ leakage current compensation technique for voltage measurement of a CMOS analog multiplexer switch. As shown in FIGS. 2A-2B, example implementation 200 includes a MEMS device 202 that includes an HV DAC 204 (e.g., a DAC capable of outputting a hundred volts or more), a CMOS analog multiplexer switch 206, and a voltage measurement system 208.

The HV DAC 204 is connected to the CMOS analog multiplexer switch 206 via a resistive network 210, where the HV DAC 204 is connected to the CMOS analog multiplexer switch 206 via respective sets of resistors 212 and respective inputs S (shown as S1, S2, and so on) of the CMOS analog multiplexer switch 206. Each input S is connected to an output D of the CMOS analog multiplexer switch 206 via an individual input switch 214, or gate, of the CMOS analog multiplexer switch 206. Each input switch 214 may be associated with a particular resistance (e.g., R_{S1} for input S1, R_{S2} for input S2, and so on) and may be associated with a particular capacitance (e.g., shown as overlapped circles), which may be on the order of a few pF with respect to voltage measurements and leakage currents described herein.

The voltage measurement system 208 is connected to the output D of the CMOS analog multiplexer switch 206, such as to facilitate voltage measurements of the inputs S of the CMOS analog multiplexer switch 206. The voltage measurement system 208 includes a first analog buffer amplifier 216, a second analog buffer amplifier 218, a resistor 220, a selector switch 222, a DAC 224, an ADC 226, and/or a controller 228.

Each analog buffer amplifier of the first analog buffer amplifier 216 and the second analog buffer amplifier 218 is a device (e.g., that includes an electronic circuit) that is operable to pass a continuous analog signal. Each analog buffer amplifier may include operational amplifiers (op-amps) (e.g., that are configured as voltage followers), transistors, feedback networks, and/or other components, that enable the analog buffer amplifier to maintain signal integrity and/or drive heavier loads. The resistor 220 is device that is operable to oppose a flow of electrical current and therefore create a voltage drop.

The selector switch 222 is a device that allows for electronically toggling connections between two (or more) electrical paths for a continuous analog signal. For example, the selector switch 222 enables a first electrical path when the selector switch 222 is in a first position and enables a second electrical path when the selector switch 222 is in a second position. The selector switch 222 may include a single pole, double throw (SPDT) switch, a single-pole single-throw (SPST) switch, and/or other components, that enable switching between electrical paths.

The DAC 224 is a device (e.g., that includes an electronic circuit) that is operable to convert a digital value, such as a binary code that is referred to as a DAC count, into a corresponding analog signal, such as a voltage, that represents the magnitude encoded by the DAC count. The DAC 224 may include a resistor ladder network (e.g., an R-2R ladder), current sources, operational amplifiers, digital control logic, and/or other components that enable the DAC 224 to generate an analog output signal based on the resolution of the DAC 224 (e.g., defined by the number of bits in the DAC count), such that each DAC count corresponds to a particular analog output level (e.g., voltage level).

The ADC 226 is a device (e.g., that includes an electronic circuit) that is operable to convert a continuous analog signal, such as voltage, into a digital value, also referred to as an ADC count, that represents a magnitude of the signal. The ADC 226 may include a sample-and-hold circuit, a comparator, digital logic, and/or other components, that enable the ADC 226 to compare a signal's measured voltage to a reference voltage and divide a result into discrete steps (e.g., based on a resolution of the ADC 226, represented by a string of bits) so that each measured voltage corresponds to a particular ADC count.

The controller 228 is a device (e.g., that includes an electronic circuit) that is operable to control at least one component of the voltage measurement system 208, such as the selector switch 222, the DAC 224, and/or the ADC 226. The controller 228 may include one or more components that enable the controller 228 to perform one or more operations further described herein in relation to a voltage sweep operation, a sequential input switch activation operation, and/or determining leakage-current-corrected voltages of the inputs S of the CMOS analog multiplexer switch 206.

In some implementations, a first input of the ADC 226 is connected to the output D of the CMOS analog multiplexer switch 206. For example, as shown in FIGS. 2A-2B, the first input of the ADC 226 is connected to the output D of the CMOS analog multiplexer switch 206 via the first analog buffer amplifier 216. As further shown in FIG. 2A, the DAC 224 is operable to connect to the output D of the CMOS analog multiplexer switch 206 via the resistor 220 (e.g., that is configured to have a resistance R_{DAC}) and to a second input of the ADC 226, such as via the second analog buffer amplifier 218, when the selector switch 222 is in a first position (e.g., a diagonal position). Further, as shown in FIG. 2B, the DAC 224 is operable to not connect to the output of the CMOS analog multiplexer switch 206 (e.g., via the resistor 220) and to the second input of the ADC 226 (e.g., via the second analog buffer amplifier 218) when the selector switch 222 is in a second position (e.g., a horizontal position).

As indicated above, FIGS. 2A-2B are provided as an example. Other examples may differ from what is described with regard to FIGS. 2A-2B. The number and arrangement of devices shown in FIGS. 2A-2B are provided as an example. In practice, there may be additional devices, fewer devices, different devices, or differently arranged devices than those shown in FIGS. 2A-2B. Furthermore, two or more devices shown in FIGS. 2A-2B may be implemented within a single device, or a single device shown in FIGS. 2A-2B may be implemented as multiple, distributed devices. Additionally, or alternatively, a set of devices (e.g., one or more devices) shown in FIGS. 2A-2B may perform one or more functions described as being performed by another set of devices shown in FIGS. 2A-2B.

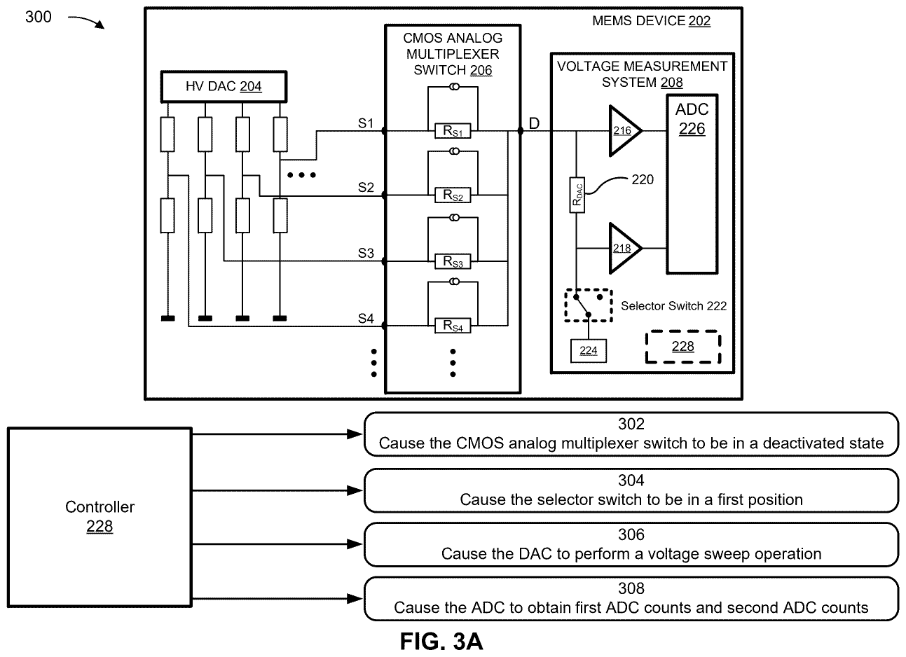

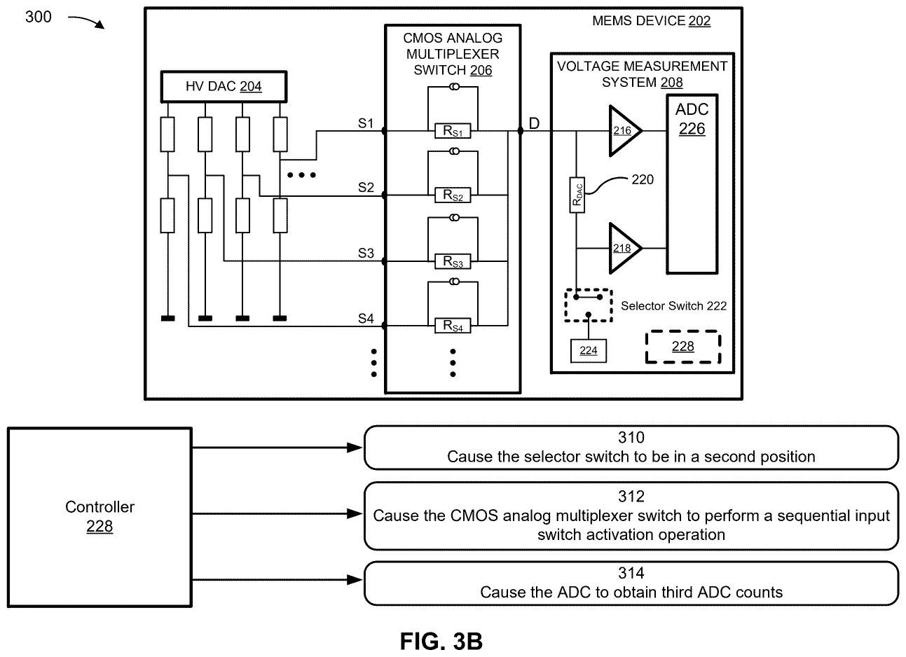

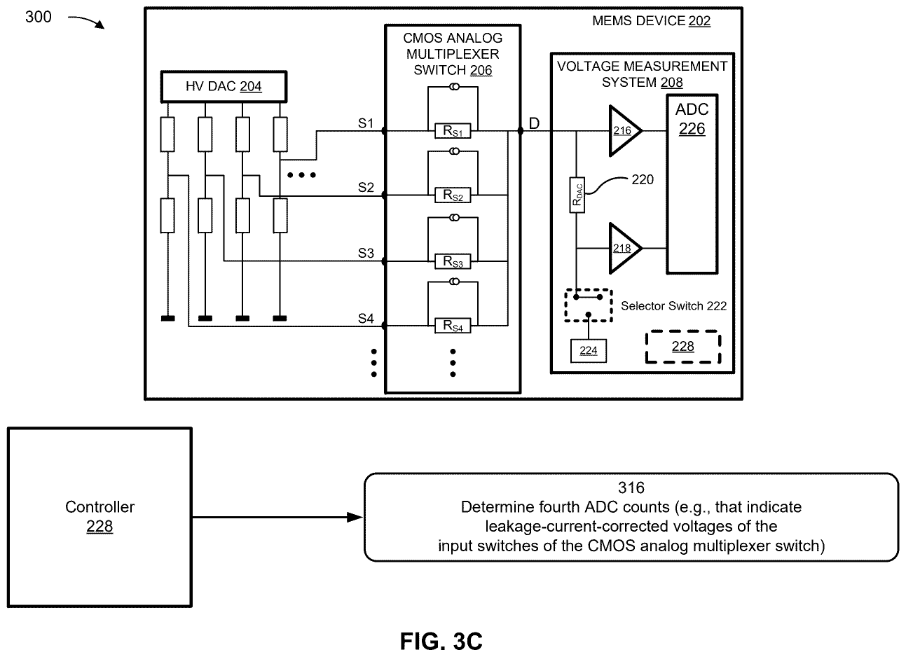

FIGS. 3A-3C are diagrams of an example implementation 300 associated with an in-situ leakage current compensation technique for voltage measurement of a CMOS analog multiplexer switch. As shown in FIGS. 3A-3C, example implementation 300 includes the MEMS device 202 that includes the HV DAC 204, the CMOS analog multiplexer switch 206, and the voltage measurement system 208 described elsewhere herein.

As shown in FIG. 3A, and by reference number 302, the controller 228 of the voltage measurement system 208 is configured to cause the CMOS analog multiplexer switch 206 to be in a deactivated state. That is, the controller 228 causes the CMOS analog multiplexer switch 206 to cease being in an active switching state, which disables any electrical connection between the inputs S and the output D of the CMOS analog multiplexer switch 206. Additionally, the controller 228 may cause the voltages at the inputs S to be constant (e.g., by controlling the HV DAC 204 of the MEMS device 202 to set constant voltages at outputs of the CMOS analog multiplexer switch 206 that connect to the inputs S of the CMOS analog multiplexer switch 206). Notably, leakage currents flow from the output D to the inputs S of the CMOS analog multiplexer switch 206 (and then to grounds of the resistive network 210) when the CMOS analog multiplexer switch 206 is in the deactivated state.

As shown by reference number 304, the controller 228 is configured to cause the selector switch 222 to be in the first position (e.g., in the diagonal position), such as based on causing the CMOS analog multiplexer switch to be in the deactivated state. For example, the controller 228 may send one or more commands to the selector switch 222 to cause the selector switch 222 to move to, or to remain at, the first position. In this way, by causing the selector switch 222 to be in the first position, the controller 228 causes the DAC 224 to be connected to the output D of the CMOS analog multiplexer switch 206 (e.g., via the resistor 220) and to the second input of the ADC 226 (e.g., via the second analog buffer amplifier 218). Notably, leakage currents flow from the output D of the CMOS analog multiplexer switch 206 to the DAC 224 when the selector switch 222 is in the first position.

As shown by reference number 306, the controller 228 is configured to cause the DAC 224 to perform a voltage sweep operation, such as based on causing the selector switch 222 to be in the first position. For example, the controller 228 may send one or more commands to the DAC 224 to incrementally vary DAC counts of the DAC 224, which causes output voltages of the DAC 224 to incrementally vary. As a specific example, the controller 228 may cause the DAC 224 to incrementally increase DAC counts from zero (0), a minimum DAC count of the DAC 224, to a maximum DAC count of the DAC 224, such as to incrementally increase an output voltage of the DAC 224 from a minimum voltage (e.g., 0 V) to a maximum voltage of the DAC 224. In some implementations, the maximum voltage of the DAC 224 is greater than or equal to a maximum voltage (e.g., a maximum potential voltage) of an input S of the CMOS analog multiplexer switch 206.

As shown by reference number 308, the controller 228 is configured to cause the ADC 226 to obtain first ADC counts associated with the DAC 224 and the voltage sweep operation. For example, the controller 228 may send one or more commands to the ADC 226 to obtain (e.g., to measure) the first ADC counts during the voltage sweep operation. The first ADC counts may indicate, for example, measured voltages at the DAC 224 for DAC counts of the voltage sweep operation. That is, the ADC 226 may obtain, for each DAC count of the DAC 224 that is associated with the voltage sweep operation, a first ADC count that indicates a measured voltage of the DAC 224 at the DAC 224.

As further shown by reference number 308, the controller 228 is configured to cause the ADC 226 to obtain second ADC counts associated with the output D of the CMOS analog multiplexer switch 206 and the voltage sweep operation. For example, the controller 228 may send one or more commands to the ADC 226 to obtain (e.g., to measure) the second ADC counts during the voltage sweep operation. The second ADC counts may indicate, for example, measured voltages at the output D of the CMOS analog multiplexer switch 206 for DAC counts of the voltage sweep operation. That is, the ADC 226 may obtain, for each DAC count of the DAC 224 that is associated with the voltage sweep operation, a second ADC count that indicates a measured voltage of the output D of the CMOS analog multiplexer switch 206 at the output D of the CMOS analog multiplexer switch 206.

In some implementations, a difference between a particular first ADC count, of the first ADC counts, and a corresponding second ADC count, of the second ADC counts, for a particular DAC count of the voltage sweep operation, indicates an ADC count error due to leakage currents in the CMOS analog multiplexer switch 206 (e.g., for the particular DAC count). Accordingly, the controller 228 may determine, for each DAC count of the voltage sweep operation, an ADC count error that is a difference between a first ADC count and a second ADC count that correspond to the DAC count.

As shown in FIG. 3B, and by reference number 310, the controller 228 is configured to cause the selector switch 222 to be in the second position (e.g., in the horizontal position), such as after completion of the voltage sweep operation. For example, the controller 228 may send one or more commands to the selector switch 222 to cause the selector switch 222 to move to the second position. In this way, by causing the selector switch 222 to be in the second position, the controller 228 causes the DAC 224 to not be connected to the output D of the CMOS analog multiplexer switch 206 (e.g., via the resistor 220) and to the second input of the ADC 226 (e.g., via the second analog buffer amplifier 218).

As shown by reference number 312, the controller 228 is configured to cause the CMOS analog multiplexer switch 206 to perform a sequential input switch activation operation, such as based on causing the selector switch 222 to be in the second position. For example, the controller 228 may send one or more commands to the CMOS analog multiplexer switch 206 to sequentially activate each input switch 214 of the CMOS analog multiplexer switch 206, while deactivating (or ceasing from activating) each other input switch 214 of the CMOS analog multiplexer switch 206. In this way, only one input switch 214, that is associated with an input S of the CMOS analog multiplexer switch 206, may be activated at an instant in time during the sequential input switch activation operation.

As shown by reference number 314, the controller 228 is configured to cause the ADC 226 to obtain third ADC counts associated with the inputs S of the CMOS analog multiplexer switch 206 and the sequential input switch activation operation. For example, the controller 228 may send one or more commands to the ADC 226 to obtain (e.g., to measure) the third ADC counts during the sequential input switch activation operation. The third ADC counts may indicate, for example, measured voltages at the output D of the CMOS analog multiplexer switch 206. Each third ADC count may be associated with a respective input S (and/or input switch 214) of the CMOS analog multiplexer switch 206 activated during the sequential input switch activation operation. Accordingly, each third ADC count may indicate a measured voltage of an input S (and/or an input switch 214) of the CMOS analog multiplexer switch 206.

As shown by reference number 316, the controller 228 is configured to determine fourth ADC counts (e.g., based on the first ADC counts, the second ADC counts, and the third

ADC counts). The fourth ADC counts may be associated with the inputs S (and/or the input switches 214) of the CMOS analog multiplexer switch 206. For example, the fourth ADC counts may indicate leakage-current-corrected voltages of the inputs S (and/or the input switches 214) of the CMOS analog multiplexer switch 206. That is, each fourth ADC count may indicate a leakage-current-corrected voltage of an input S (and/or an input switch 214 that corresponds to the input S) of the CMOS analog multiplexer switch 206.

In some implementations, to determine a particular fourth ADC count, the controller 228 may identify a particular third ADC count, of the third ADC counts, that indicates a measured voltage of a particular input S (and/or a particular input switch 214) of the CMOS analog multiplexer switch 206. The controller 228 then may identify a particular second ADC count, of the second ADC counts, that is associated with the particular third ADC count. The particular second ADC count may be maximum among all other second ADC counts, of the second ADC counts, that are less than or equal to the particular third ADC count. The controller 228 then may identify a particular first ADC count that corresponds to the second particular ADC count (e.g., each of the particular first ADC count and the second particular ADC are associated with a particular DAC count of the DAC 224 of the voltage sweep operation). Accordingly, the controller 228 may determine the particular fourth ADC count based on the particular first ADC count, the particular second ADC count, and the particular third ADC count. For example, the controller 228 may add, to the third particular ADC count, a difference between the particular first ADC count and the particular second ADC count. That is, the controller 228 may add an ADC count error due to leakage currents (e.g., described above) that is associated with the particular third ADC count to the particular third ADC count to determine the particular fourth ADC count. Accordingly, the particular fourth ADC count may indicate a leakage-current-corrected voltage of the particular input S (and/or the particular input switch 214) of the CMOS analog multiplexer switch 206.

In some implementations, operations described herein with respect to FIGS. 3A-3C are performed within a time window, which may be on the order of 100 msec or less. Due to this limited time window, effects on components of the MEMS device 202 due to changes in ambient temperature are reduced. Further, in some implementations, the operations described herein with respect to FIGS. 3A-3C may be iteratively performed, such as on a scheduled basis. For example, the operations may be performed every few seconds, every few minutes, or longer. In this way, leakage-current-corrected voltages may be determined from time-to-time, such as to compensate for gradual changes in ambient temperature over time.

As indicated above, FIGS. 3A-3C are provided as an example. Other examples may differ from what is described with regard to FIGS. 3A-3C. The number and arrangement of devices shown in FIGS. 3A-3C are provided as an example. In practice, there may be additional devices, fewer devices, different devices, or differently arranged devices than those shown in FIGS. 3A-3C. Furthermore, two or more devices shown in FIGS. 3A-3C may be implemented within a single device, or a single device shown in FIGS. 3A-3C may be implemented as multiple, distributed devices. Additionally, or alternatively, a set of devices (e.g., one or more devices) shown in FIGS. 3A-3C may perform one or more functions described as being performed by another set of devices shown in FIGS. 3A-3C.

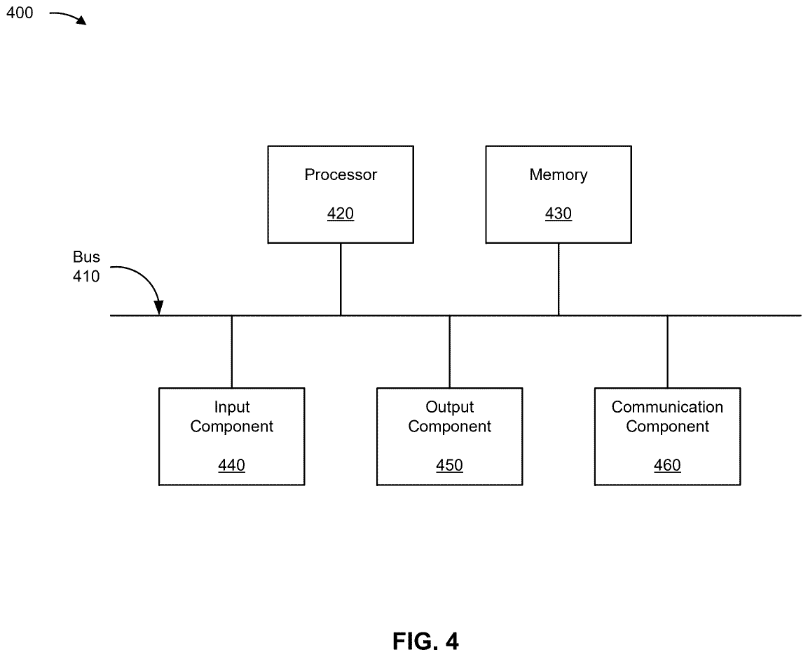

FIG. 4 is a diagram of example components of a device 400 associated with an in-situ leakage current compensation technique for voltage measurement of a complementary metal oxide semiconductor analog multiplexer switch. The device 400 corresponds to one or more of the MEMS device 202, the HV DAC 204, the CMOS analog multiplexer switch 206, the voltage measurement system 208, and/or components thereof, such as the selector switch 222, the DAC 224, the ADC 226, and/or the controller 228. In some implementations, the MEMS device 202, the HV DAC 204, the CMOS analog multiplexer switch 206, the voltage measurement system 208, and/or components thereof, such as the selector switch 222, the DAC 224, the ADC 226, and/or the controller 228 include one or more devices 400 and/or one or more components of the device 400. In the example shown in FIG. 4, the device 400 includes a bus 410, a processor 420, a memory 430, an input component 440, an output component 450, and/or a communication component 460.

The bus 410 includes one or more components that enable wired and/or wireless communication among the components of the device 400. The bus 410 couples together two or more components of FIG. 4, such as via operative coupling, communicative coupling, electronic coupling, and/or electric coupling. For example, the bus 410 may include an electrical connection (e.g., a wire, a trace, and/or a lead) and/or a wireless bus. The processor 420 includes a central processing unit, a graphics processing unit, a microprocessor, a controller, a microcontroller, a digital signal processor, a field-programmable gate array, an application-specific integrated circuit, and/or another type of processing component. The processor 420 may be implemented in hardware, firmware, or a combination of hardware and software. In some implementations, the processor 420 includes one or more processors capable of being programmed to perform one or more operations or processes described elsewhere herein.

The memory 430 includes volatile and/or nonvolatile memory, such as random access memory (RAM), read only memory (ROM), a hard disk drive, and/or another type of memory (e.g., a flash memory, a magnetic memory, and/or an optical memory). The memory 430 may include internal memory (e.g., RAM, ROM, or a hard disk drive) and/or removable memory (e.g., removable via a universal serial bus connection). In some implementations, the memory 430 is a non-transitory computer-readable medium. The memory 430 stores information, one or more instructions, and/or software (e.g., one or more software applications) related to the operation of the device 400. In some implementations, the memory 430 includes one or more memories that are coupled (e.g., communicatively coupled) to one or more processors (e.g., processor 420), such as via the bus 410. Communicative coupling between a processor 420 and a memory 430 enables the processor 420 to read and/or process information stored in the memory 430 and/or to store information in the memory 430.

The input component 440 enables the device 400 to receive input, such as user input and/or sensed input. For example, the input component 440 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 450 enables the device 400 to provide output, such as via a display, a speaker, and/or a light-emitting diode. The communication component 460 enables the device 400 to communicate with other devices via a wired connection and/or a wireless connection. For example, the communication component 460 may include a receiver, a transmitter, a transceiver, a modem, a network interface card, and/or an antenna.

In some implementations, the device 400 performs one or more operations or processes described herein. For example, a non-transitory computer-readable medium (e.g., memory 430) may store a set of instructions (e.g., one or more instructions or code) for execution by the processor 420. The processor 420 may execute the set of instructions to perform one or more operations or processes described herein. In some implementations, execution of the set of instructions, by one or more processors 420, causes the one or more processors 420 and/or the device 400 to perform one or more operations or processes described herein. In some implementations, hardwired circuitry is used instead of or in combination with the instructions to perform one or more operations or processes described herein. Additionally, or alternatively, the processor 420 may be configured to perform one or more operations or processes described herein. Thus, implementations described herein are not limited to any specific combination of hardware circuitry and software.

The number and arrangement of components shown in FIG. 4 are provided as an example. The device 400 may include additional components, fewer components, different components, or differently arranged components than those shown in FIG. 4. Additionally, or alternatively, a set of components (e.g., one or more components) of the device 400 may perform one or more functions described as being performed by another set of components of the device 400.

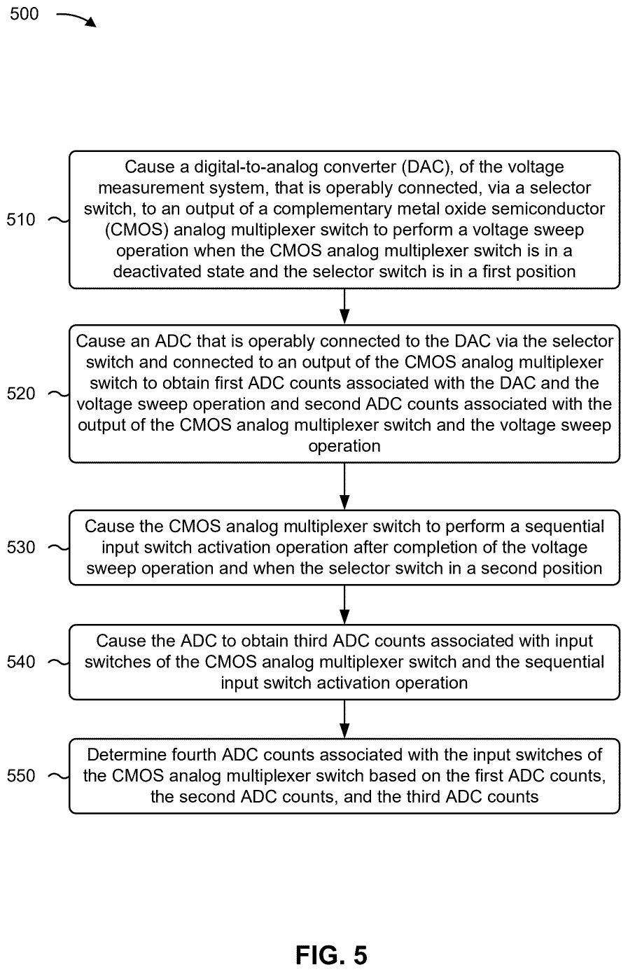

FIG. 5 is a flowchart of an example process 500 associated with an in-situ leakage current compensation technique for voltage measurement of a CMOS analog multiplexer switch. One or more process blocks of FIG. 5 are performed by a controller (e.g., the controller 228) of a voltage measurement system (e.g., the voltage measurement system) of a MEMS device (e.g., the MEMS device 202) and/or by another device or a group of devices separate from or including the controller, such as another device of the MEMS device. Additionally, or alternatively, one or more process blocks of FIG. 5 may be performed by one or more components of device 400, such as processor 420, memory 430, input component 440, output component 450, and/or communication component 460.

As shown in FIG. 5, process 500 includes causing a DAC, of the voltage measurement system, that is operably connected, via a selector switch, to an output of a CMOS analog multiplexer switch to perform a voltage sweep operation when the CMOS analog multiplexer switch is in a deactivated state and the selector switch is in a first position (block 510). For example, the controller may cause a DAC, of the voltage measurement system, that is operably connected, via a selector switch, to an output of a CMOS analog multiplexer switch to perform a voltage sweep operation when the CMOS analog multiplexer switch is in a deactivated state and the selector switch is in a first position, as described above.

As further shown in FIG. 5, process 500 includes causing an ADC that is operably connected to the DAC via the selector switch and connected to an output of the CMOS analog multiplexer switch to obtain first ADC counts associated with the DAC and the voltage sweep operation and second ADC counts associated with the output of the CMOS analog multiplexer switch and the voltage sweep operation (block 520). For example, the controller may cause an ADC that is operably connected to the DAC via the selector switch and connected to an output of the CMOS analog multiplexer switch to obtain first ADC counts associated with the DAC and the voltage sweep operation and second ADC counts associated with the output of the CMOS analog multiplexer switch and the voltage sweep operation, as described above.

As further shown in FIG. 5, process 500 includes causing the CMOS analog multiplexer switch to perform a sequential input switch activation operation after completion of the voltage sweep operation and when the selector switch in a second position (block 530). For example, the controller may cause the CMOS analog multiplexer switch to perform a sequential input switch activation operation after completion of the voltage sweep operation and when the selector switch in a second position, as described above.

As further shown in FIG. 5, process 500 includes causing the ADC to obtain third ADC counts associated with input switches of the CMOS analog multiplexer switch and the sequential input switch activation operation (block 540). For example, the controller may cause the ADC to obtain third ADC counts associated with input switches of the CMOS analog multiplexer switch and the sequential input switch activation operation, as described above.

As further shown in FIG. 5, process 500 includes determining fourth ADC counts associated with the input switches of the CMOS analog multiplexer switch based on the first ADC counts, the second ADC counts, and the third ADC counts (block 550). For example, the controller may determine fourth ADC counts associated with the input switches of the CMOS analog multiplexer switch based on the first ADC counts, the second ADC counts, and the third ADC counts, as described above.

Process 500 may include additional aspects, such as any single aspect or any combination of aspects described below and/or in connection with one or more other processes described elsewhere herein.

In a first aspect, the first ADC counts indicate measured voltages at the DAC for DAC counts of the voltage sweep operation.

In a second aspect, alone or in combination with the first aspect, the second ADC counts indicate measured voltages at the output of the CMOS analog multiplexer switch for DAC counts of the voltage sweep operation.

In a third aspect, alone or in combination with one or more of the first and second aspects, the third ADC counts indicate measured voltages at the output of the CMOS analog multiplexer switch, each associated with a respective input switch of the CMOS analog multiplexer switch activated during the sequential input switch activation operation.

In a fourth aspect, alone or in combination with one or more of the first through third aspects, the fourth ADC counts indicate leakage-current-corrected voltages of the input switches of the CMOS analog multiplexer switch.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A voltage measurement system, comprising:
a first analog buffer amplifier;
a second analog buffer amplifier;
a resistor;
a single pole, double throw (SPDT) switch;
a digital-to-analog converter (DAC); and
an analog-to-digital converter (ADC), wherein:
a first input of the ADC is connected to an output of a complementary metal oxide semiconductor (CMOS) analog multiplexer switch via the first analog buffer amplifier,
the DAC is operable to connect to the output of the CMOS analog multiplexer switch via the resistor and to a second input of the ADC via the second analog buffer amplifier when the SPDT is in a first position, and
the DAC is operable to not connect to the output of the CMOS analog multiplexer switch via the resistor and to the second input of the ADC via the second analog buffer amplifier when the SPDT is in a second position.

2. The voltage measurement system of claim 1, further comprising:
a controller configured to:
cause the CMOS analog multiplexer switch to be in a deactivated state;
cause, based on causing the CMOS analog multiplexer switch to be in the deactivated state, the SPDT to be in the first position;
cause, based on causing the SPDT to be in the first position, the DAC to perform a voltage sweep operation; and
cause the ADC to obtain first ADC counts associated with the DAC and the voltage sweep operation, and second ADC counts associated with the output of the CMOS analog multiplexer switch and the voltage sweep operation.

3. The voltage measurement system of claim 2, wherein the first ADC counts indicate measured voltages at the DAC for DAC counts of the voltage sweep operation.

4. The voltage measurement system of claim 2, wherein the second ADC counts indicate measured voltages at the output of the CMOS analog multiplexer switch for DAC counts of the voltage sweep operation.

5. The voltage measurement system of claim 2, wherein a difference between a particular first ADC count, of the first ADC counts, and a corresponding second ADC count, of the second ADC counts, for a particular DAC count of the voltage sweep operation, indicates an ADC count error due to leakage currents in the CMOS analog multiplexer switch.

6. The voltage measurement system of claim 2, wherein the controller is further configured to:
cause, after completion of the voltage sweep operation, the SPDT to be in the second position;
cause, based on causing the SPDT to be in the second position, the CMOS analog multiplexer switch to perform a sequential input switch activation operation; and
cause the ADC to obtain third ADC counts associated with inputs of the CMOS analog multiplexer switch and the sequential input switch activation operation.

7. The voltage measurement system of claim 6, wherein the third ADC counts indicate measured voltages at the output of the CMOS analog multiplexer switch, each third ADC count associated with a respective input switch of the CMOS analog multiplexer switch activated during the sequential input switch activation operation.

8. The voltage measurement system of claim 6, wherein the controller is further configured to:
determine, based on the first ADC counts, the second ADC counts, and the third ADC counts, fourth ADC counts associated with the input switches of the CMOS analog multiplexer switch.

9. The voltage measurement system of claim 8, wherein the fourth ADC counts indicate leakage-current-corrected voltages of the input switches of the CMOS analog multiplexer switch.

10. The voltage measurement system of claim 1, wherein the voltage measurement system is included in a micro-electro-mechanical systems (MEMS) device.

11. A micro-electro-mechanical systems (MEMS) device, comprising:
a resistor;
a single pole, double throw (SPDT) switch;
a digital-to-analog converter (DAC);
an analog-to-digital converter (ADC); and
a controller, wherein:
a first input of the ADC is connected to an output of a complementary metal oxide semiconductor (CMOS) analog multiplexer switch of the MEMS device, and
the DAC is operable to connect to the output of the CMOS analog multiplexer switch via the resistor and to a second input of the ADC when the SPDT is in a first position.

12. The MEMS device of claim 11, wherein the controller is configured to:
cause, based on the CMOS analog multiplexer switch being in a deactivated state, the SPDT to be in the first position;
cause, based on causing the SPDT to be in the first position, the DAC to perform a voltage sweep operation; and
cause the ADC to obtain first ADC counts associated with the DAC and the voltage sweep operation and second ADC counts associated with the output of the CMOS analog multiplexer switch and the voltage sweep operation.

13. The MEMS device of claim 12, wherein the controller is configured to:
cause, after completion of the voltage sweep operation, the SPDT to be in a second position;
cause, based on causing the SPDT to be in the second position, the CMOS analog multiplexer switch to perform a sequential input switch activation operation; and
cause the ADC to obtain third ADC counts associated with inputs of the CMOS analog multiplexer switch and the sequential input switch activation operation.

14. The MEMS device of claim 13, wherein the controller is configured to:
determine, based on the first ADC counts, the second ADC counts, and the third ADC counts, fourth ADC counts associated with the inputs of the CMOS analog multiplexer switch.

15. The MEMS device of claim 14, wherein the fourth ADC counts indicate leakage-current-corrected voltages of the inputs of the CMOS analog multiplexer switch.

16. A method, comprising:
causing, by a controller of a voltage measurement system, a digital-to-analog converter (DAC), of the voltage measurement system, that is operably connected, via a selector switch, to an output of a complementary metal oxide semiconductor (CMOS) analog multiplexer switch to perform a voltage sweep operation when the CMOS analog multiplexer switch is in a deactivated state and the selector switch is in a first position;
causing, by the controller, an ADC that is operably connected to the DAC via the selector switch and connected to an output of the CMOS analog multiplexer switch to obtain first ADC counts associated with the DAC and the voltage sweep operation and second ADC counts associated with the output of the CMOS analog multiplexer switch and the voltage sweep operation;
causing, by the controller, the CMOS analog multiplexer switch to perform a sequential input switch activation operation after completion of the voltage sweep operation and when the selector switch in a second position;
causing, by the controller, the ADC to obtain third ADC counts associated with input switches of the CMOS analog multiplexer switch and the sequential input switch activation operation; and
determining, by the controller, fourth ADC counts associated with the input switches of the CMOS analog multiplexer switch based on the first ADC counts, the second ADC counts, and the third ADC counts.

17. The method of claim 16, wherein the first ADC counts indicate measured voltages at the DAC for DAC counts of the voltage sweep operation.

18. The method of claim 16, wherein the second ADC counts indicate measured voltages at the output of the CMOS analog multiplexer switch for DAC counts of the voltage sweep operation.

19. The method of claim 16, wherein the third ADC counts indicate measured voltages at the output of the CMOS analog multiplexer switch, each associated with a respective input switch of the CMOS analog multiplexer switch activated during the sequential input switch activation operation.

20. The method of claim 16, wherein the fourth ADC counts indicate leakage-current-corrected voltages of the input switches of the CMOS analog multiplexer switch.
